(19) United States
(12) Patent Application Publication
(10) Pub. No.: US 2026/0185217 A1
(43) Pub. Date: Jul. 2, 2026

(54) Y2O3 THIN FILM HAVING PLASMA ETCHING RESISTANCE AND ITS MANUFACTURING METHOD

(71) Applicants: ICHEMS Co., Ltd., Gyeonggi-do (KR); Pusan National University Industry-University Cooperation Foundation, Geumjeong-gu (KR); EG Chem Co., Ltd., Chungcheongnam-do (KR)

(72) Inventors: Seong LEE, Busan (KR); Hyunchang KIM, Chungcheongbuk-do (KR); Se Hun KWON, Geumjeong-gu (KR)

(73) Assignees: ICHEMS Co., Ltd., Gyeonggi-do (KR); Pusan National University Industry-University Cooperation Foundation, Geumjeong-gu (KR); EG Chem Co., Ltd., Chungcheongnam-do (KR)

(21) Appl. No.: 19/433,157

(22) Filed: Dec. 26, 2025

(30) Foreign Application Priority Data
Dec. 26, 2024 (KR) 10-2024-0197675
Dec. 24, 2025 (KR) 10-2025-0209503

(51) Int. Cl. C23C 16/40; C23C 16/44; C23C 16/455; H01J 37/32

(52) U.S. Cl. CPC C23C 16/405; C23C 16/4408; C23C 16/45527; C23C 16/45553; H01J 37/32467; H01J 37/32495; H01J 37/32807; H01J 2237/0213

(57) ABSTRACT

A method for manufacturing a Y₂O₃ thin film capable of exhibiting resistance to fluorocarbon-based high-density plasma is described. An ALD-Y₂O₃ thin film is manufactured using bis(methylcyclopentadienyl)(N′-isopropyl-N-n-propylacetamidinate) yttrium (Y(MeCp)₂(iPr-nPrAMD)) as a precursor.

### CROSS REFERENCE TO RELATED APPLICATIONS

This application claims priority to Korean Patent Application No. 10-2024-0197675 filed on Dec. 26, 2024, and Korean Patent Application No. 10-2025-0209503 filed on Dec. 24, 2025, in the Korean Intellectual Property Office. The content of these applications is incorporated herein by reference in its entirety.

The present invention relates to a Y₂O₃ thin film having plasma etching resistance and a method for manufacturing the same.

### BACKGROUND ART

Oxide ceramics such as Al₂O₃ and SiO₂ are commonly used to protect semiconductor components from plasma erosion and particle contamination. However, due to the high power levels of fluorine-based plasma equipment, the performance of Al₂O₃ and SiO₂ coatings has become increasingly problematic. In addition, these materials have been shown to be vulnerable to fluorine-based plasma etching processes when exposed to repetitive cycles within a chamber. To address these issues, yttrium oxide (Y₂O₃) has been increasingly proposed as a protective coating material because of its low etching rate and low chemical reactivity.

Korean Patent Publication No. 10-2017-0006807 proposes a technique for depositing yttria on component parts by chemical vapor deposition, using precursors such as tris[N,N-bis(trimethylsilyl)amide]yttrium (YTDTMSA). However, the above publication does not describe at all whether the yttria (Y₂O₃) thin film deposited thereby has durability against fluorinated plasma chemical etching reactions.

### DISCLOSURE OF THE INVENTION

### Problems to be Solved

An object of the present invention is to provide a method for manufacturing a Y₂O₃ thin film capable of exhibiting resistance to fluorocarbon-based high-density plasma.

The present invention investigates precursors used for manufacturing a Y₂O₃ thin film, examines ALD growth kinetics of the resulting thin film, and systematically analyzes the dependence of the growth rate and physical properties of the Y₂O₃ thin film on growth temperature. Finally, etching resistance characteristics of an ALD-Y₂O₃ thin film in fluorine-based plasma are thoroughly discussed.

### Means for Solving the Problems

In accordance with the above object, the present invention manufactures an ALD-Y₂O₃ thin film using bis(methylcyclopentadienyl)(N′-isopropyl-N-n-propylacetamidinate) yttrium (Y(MeCp)₂(iPr-nPrAMD)) as a precursor.

That is, the present invention provides a method for manufacturing a Y₂O₃ thin film, characterized by using bis(methylcyclopentadienyl)(N′-isopropyl-N-n-propylacetamidinate) yttrium (Y(MeCp)₂(iPr-nPrAMD)) as a precursor and employing atomic layer deposition (ALD).

In the above, one or more reactants selected from H₂O, O₃, O₂, and H₂O₂ are used together with the Y(MeCp)₂(iPr-nPrAMD) precursor.

That is, the present invention provides a method for manufacturing a Y₂O₃ thin film, characterized by using bis(methylcyclopentadienyl)(N′-isopropyl-N-n-propylacetamidinate) yttrium (Y(MeCp)₂(iPr-nPrAMD)) as a precursor, employing atomic layer deposition (ALD), and using one or more reactants selected from H₂O, O₃, O₂, and H₂O₂.

In the above, one ALD cycle includes injecting Y(MeCp)₂(iPr-nPrAMD) with an inert gas at 30-100 sccm for a predetermined time t₁, purging with an inert gas at 30-100 sccm for time t₂, injecting an H₂O reactant at 30-100 sccm for time t₃, and again purging with an inert gas at 30-100 sccm for time t₄.

In the above, the thin film growth temperature may be controlled in a range from 150° C. to 350° C.

In the above, t₁ is 3 seconds or less.

In the above, t₂ and t₄ are 18 to 22 seconds, and t₃ is 2 to 22 seconds.

In the above, Y(MeCp)₂(iPr-nPrAMD) is chemisorbed in a self-limiting manner, such that a thickness of the formed Y₂O₃ thin film can be increased linearly according to an increase in the number of ALD cycles.

The present invention further provides a method for forming a protective coating material for a semiconductor manufacturing component, characterized in that a Y₂O₃ thin film is formed as a protective coating against fluorinated plasma chemical etching on a semiconductor manufacturing component by the above-described method for manufacturing a Y₂O₃ thin film.

The present invention further provides a semiconductor manufacturing component including a Y₂O₃ protective coating material having resistance to fluorinated plasma chemical etching, formed by the above-described method for forming a protective coating material for a semiconductor manufacturing component.

### Effects of the Invention

According to the present invention, an ALD-Y₂O₃ thin film manufactured using bis(methylcyclopentadienyl)(N′-isopropyl-N-n-propylacetamidinate) yttrium (Y(MeCp)₂(iPr-nPrAMD)) as a precursor exhibits strong etching resistance in fluorine-based plasma.

According to the present invention, an ALD-Y₂O₃ thin film manufactured using Y(MeCp)₂(iPr-nPrAMD) as a precursor is of high purity and high density, has a wide ALD temperature window, and exhibits properties similar to bulk Y₂O₃, thereby being a promising film for various applications including protective coatings against CF₄-based plasma.

According to the present invention, a formation process of an ALD-Y₂O₃ thin film manufactured using Y(MeCp)₂(iPr-nPrAMD) as a precursor exhibits a self-limiting reaction mechanism, such that growth of the ALD-Y₂O₃ thin film shows linearity with respect to ALD cycles, thereby enabling precise digital control of thin film thickness.

### BRIEF DESCRIPTION OF THE DRAWINGS

FIG. 1(a) illustrates a growth rate of an ALD-Y₂O₃ thin film at 260° C. as a function of a Y(MeCp)₂(iPr-nPrAMD) pulse time and an H₂O pulse time; (b) illustrates H₂O pulse time at a growth temperature of 260° C.; (c) illustrates thickness of ALD-Y₂O₃ thin films as a function of the number of ALD cycles at a growth temperature of 260° C.; and (d) illustrates growth rate and refractive index of ALD-Y2O3 thin films depending on the growth temperature from 150 to 290° C., a growth rate and refractive index of an ALD-Y₂O₃ thin film as a function of growth temperature between 150° C. and 290° C., and (d) illustrates the effect of growth temperature on the growth rate and refractive index of the Y₂O₃ thin film.

FIG. 2(a) illustrates XRD patterns of ALD-Y₂O₃ thin films as a function of deposition temperature between 150° C. and 290° C., and (b) illustrates XRR patterns thereof.

FIG. 3(a) illustrates an AES depth profile of an ALD-Y₂O₃ thin film prepared at a deposition temperature of 150° C., and (b) illustrates an AES depth profile of an ALD-Y₂O₃ thin film prepared at a deposition temperature of 290° C.

FIG. 4 illustrates plasma etching rates of ALD-Al₂O₃ and ALD-Y₂O₃ thin films, which were calculated based on a difference in film thickness before and after RIE performed for 15 minutes.

### DETAILED DESCRIPTION

Hereinafter, preferred embodiments of the present invention will be described in detail with reference to the accompanying drawings.

Atomic layer deposition (ALD) of a Y₂O₃ thin film using a Y(MeCp)₂(iPr-nPrAMD) precursor and an H₂O reactant was investigated. At a growth temperature of 260° C., a self-limiting reaction mechanism of the ALD-Y₂O₃ thin film was confirmed. In addition, a saturated growth rate was confirmed to be approximately 0.11 nm/cycle. It was also found that a consistent growth rate was maintained over a wide ALD temperature window from 150° C. to 290° C.

The ALD-Y₂O₃ thin film was confirmed to have a typical cubic polycrystalline structure regardless of the growth temperature, which may be attributed to the stoichiometric composition of Y₂O₃, negligible carbon impurities, and a high film density. Even at a low growth temperature of 150° C., ALD-Y₂O₃ exhibited a significantly lower plasma etching rate (˜0.77 nm/min) compared to that of ALD-Al₂O₃ (˜4.6 nm/min) when reactive ion etching (RIE) was performed using a mixed gas of Ar/CF₄/O₂ and a plasma power of 400 W. In addition, the growth temperature of the Y₂O₃ thin film had little effect on the etching rate.

### 1. Introduction

In the semiconductor industry, miniaturized semiconductor devices are sensitive to particle and metal contamination, making this issue a matter of significant concern. For example, three-dimensional vertical NAND (3D V-NAND) technology is used to directly reduce circuit linewidths on wafers by stacking circuits in multiple layers. Accordingly, dry etching processes using fluorocarbon-based high-density plasma are repeatedly performed in chambers, and ceramic equipment components are simultaneously exposed to the plasma atmosphere. Moreover, fluorocarbon plasma bombards and erodes inner wall materials of equipment components. In particular, a showerhead facing a wafer may undergo substantial etching under severe high-density plasma flux. Such erosion of equipment components and generation of contaminant particles cause serious problems that reduce yield in mass production. Therefore, recent intensive efforts have focused on the development of advanced protective coating materials and appropriate deposition technologies to minimize equipment component erosion and reduce generation of contaminant particles. A key requirement for coatings on equipment components is that the coating itself should not emit particles and should not contain metallic contaminants. Accordingly, the coating should exhibit high corrosion resistance and erosion resistance under various chemical and plasma conditions. To reduce corrosion, ceramic coatings that provide excellent resistance to fluorine plasma may be used.

Oxide ceramics such as Al₂O₃ and SiO₂ are commonly used to protect semiconductor components from plasma erosion and particle contamination. However, due to the high power levels of fluorine-based plasma equipment, the performance of Al₂O₃ and SiO₂ coatings has increasingly become problematic. In addition, these materials have been shown to be vulnerable to fluorine-based plasma etching processes when exposed to repetitive cycles within a chamber. To address these issues, yttrium oxide (Y₂O₃) has been increasingly proposed as a protective coating material because of its low etching rate and low chemical reactivity.

Y₂O₃ possesses many advantageous properties that make it highly attractive for various industrial applications. These properties include a wide energy band gap (5.5 eV to 5.8 eV), a band offset (2.3 eV), a relatively high dielectric constant (14 to 18), a high refractive index (1.9), a high melting point (2430° C.) ensuring excellent thermal stability, and good thermal conductivity (κ=0.33 W·cm⁻¹·K⁻¹). In particular, Y₂O₃ exhibits impressive wear resistance, high mechanical and dielectric strength, and excellent corrosion resistance and chemical stability, making it an ideal choice as a protective coating for fluorine-based plasma equipment components.

To date, Y₂O₃ protective coatings have been extensively studied using various deposition techniques such as atmospheric plasma spraying (APS), vacuum plasma spraying (VPS), physical vapor deposition (PVD), and chemical vapor deposition (CVD). However, to improve protective performance and reduce coating thickness, defects such as pore formation, impurities, and poor conformality must be addressed. In this regard, atomic layer deposition (ALD) technology has recently attracted attention as a feasible method for forming Y₂O₃ protective coatings. In this process, gaseous precursor molecules are introduced into a chamber and react with a substrate surface to grow a thin film in a layer-by-layer manner. Major advantages of ALD include atomic-scale deposition and an inherently self-limiting growth mechanism, which provide several benefits such as precise atomic-scale thickness control, fully conformal and pinhole-free coatings, and excellent step coverage on highly complex structures. Furthermore, recent development of batch-type ALD equipment has accelerated the application of ALD protective layers to large-scale components.

ALD-Y₂O₃ has been demonstrated using various precursors such as Y(MeCp)₃, Y(EtCp)₃, Y(iPrCp)₃, Y(thd)₃, and Y(EtCp)₂(iPr₂-amd), together with oxidants such as H₂O and O₃. However, most studies on ALD-Y₂O₃ have focused primarily on high-k dielectric applications, and there have been very few reports on corrosion resistance against fluorine-based plasma. In addition, the relatively narrow ALD temperature windows of some precursors may limit their potential for various industrial applications, thereby requiring further improvement. For example, the ALD temperature window of Y(MeCp)₃ is between 250° C. and 300° C. Y(EtCp)₃ and Y(iPrCp)₃ also exhibit narrow ALD temperature windows (250° C. to 280° C. for Y(EtCp)₃ and 245° C. to 300° C. for Y(iPrCp)₃). In the case of the Y(EtCp)₂(iPr₂-amd) precursor, the ALD temperature window is 300° C. to 450° C., which may limit low-temperature applications. On the other hand, Y(thd)₃ exhibits a relatively wide ALD temperature window from 250° C. to 375° C.; however, high carbon and hydrogen impurities have also been reported for Y(thd)₃.

Accordingly, in the present invention, ALD-Y₂O₃ thin films were investigated using bis(methylcyclopentadienyl)(N′-isopropyl-N-n-propylacetamidinate) yttrium (Y(MeCp)₂(iPr-nPrAMD)). The ALD growth kinetics of Y(MeCp)₂(iPr-nPrAMD) were closely examined. In addition, the dependence of the growth rate and physical properties of the Y₂O₃ thin films on growth temperature was systematically analyzed. Finally, etching resistance characteristics of the ALD-Y₂O₃ thin films in fluorine-based plasma were thoroughly discussed.

### 2. Materials and Methods

Y₂O₃ thin films were deposited on p-type Si (100) wafers by atomic layer deposition (ALD) at growth temperatures ranging from 150° C. to 290° C. As a precursor, bis(methylcyclopentadienyl)(N′-isopropyl-N-n-propylacetamidinate) yttrium (Y(MeCp)₂(iPr-nPrAMD), iChems Co., Ltd.) was used, and H₂O was used as a reactant. Y(MeCp)₂(iPr-nPrAMD) and H₂O were maintained in separate containers at 120° C. and room temperature, respectively, to provide sufficient vapor pressure. In the present invention, in addition to H₂O, various oxidants such as O₃, O₂, and H₂O₂ may be used as reactants. That is, embodiments based on H₂O may be carried out under otherwise identical conditions by substituting O₃, O₂, or H₂O₂ as the reactant.

One ALD cycle includes injecting Y(MeCp)₂(iPr-nPrAMD) with an inert gas at 30-100 sccm, preferably 45-55 sccm, for a predetermined time t₁; purging with an inert gas at 30-100 sccm, preferably 45-55 sccm, for time t₂; injecting the H₂O reactant at 30-100 sccm, preferably 45-55 sccm, for time t₃; and again purging with an inert gas at 30-100 sccm, preferably 45-55 sccm, for time t₄. The chamber operating pressure may be maintained at 1.08×10⁻¹ Torr to 1.32×10⁻¹ Torr.

As a preferred embodiment, one ALD cycle for Y₂O₃ consisted of injecting Y(MeCp)₂(iPr-nPrAMD) with 50 sccm of Ar for 3 seconds, purging with 50 sccm of Ar for 20 seconds, injecting the H₂O reactant at 50 sccm for 2 seconds, and again purging with 50 sccm of Ar for 20 seconds. The chamber operating pressure was maintained at 1.2×10⁻¹ Torr.

In the above, t₂ and t₄ may be 18 to 22 seconds, and t₃ may be 2 to 22 seconds.

Sets of ALD-Y₂O₃ thin films were deposited while varying the growth temperature from 100° C. to 350° C., preferably from 150° C. to 290° C. Y₂O₃ thin films deposited at 150° C., 180° C., 220° C., 260° C., and 290° C. were designated as Y₂O₃—150, Y₂O₃—180, Y₂O₃—220, Y₂O₃—260, and Y₂O₃—290, respectively. The number of repeated ALD cycles was intentionally adjusted, regardless of growth temperature, to obtain similar film thicknesses of approximately 30 nm (27-33 nm), thereby minimizing the effect of film thickness on the physical and chemical properties of the Y₂O₃ thin films.

Film thickness and the corresponding refractive index were analyzed using spectroscopic ellipsometry (α-SE, J. A. Woollam Co., Inc.). Crystalline structure and film density were determined by X-ray diffraction (XRD) and X-ray reflectivity (XRR) using a Rigaku SmartLab diffractometer (D/MAX-2500V) with Cu-Kα₁ radiation. In addition, depth profiles of composition were investigated using Auger electron spectroscopy (AES, PHI-710, ULVAC-PHI). Surface morphology was examined by atomic force microscopy (AFM).

High-density plasma resistance was investigated using reactive ion etching (RIE, LABStar, TTL) at a plasma power of 400 W and a pressure of 50 mTorr, using a mixed gas of Ar (50 sccm), CF₄ (45 sccm), and O₂ (5 sccm) for 15 minutes.

### 3. Results and Discussion

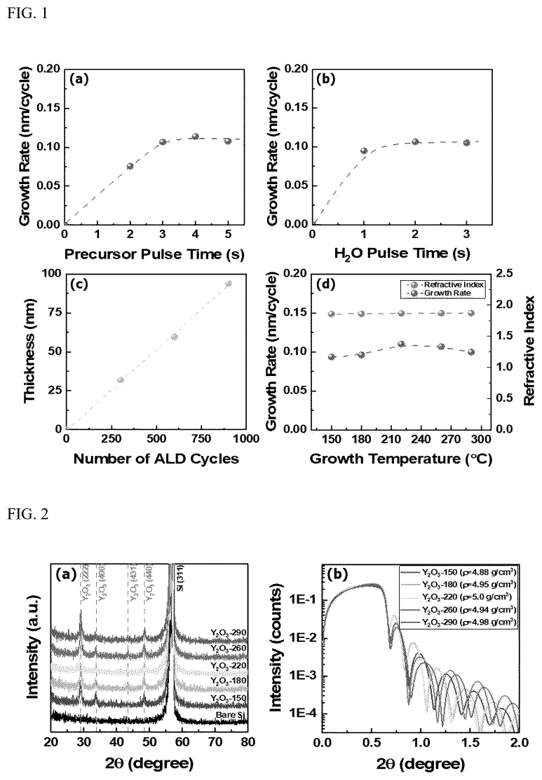

First, self-limiting growth behavior of the ALD-Y₂O₃ thin films was investigated. FIG. 1(a) shows the growth rate of the Y₂O₃ thin film as a function of the Y(MeCp)₂(iPr-nPrAMD) pulse time in order to confirm the ALD reaction mechanism at a constant growth temperature of 260° C. In one ALD cycle, pulses other than the Y(MeCp)₂(iPr-nPrAMD) precursor pulse were fixed at a 20-second purge, a 10-second H₂O reactant pulse, and another 20-second purge.

As the Y(MeCp)₂(iPr-nPrAMD) pulse time increased from 2 seconds to 5 seconds, the growth rate increased and became saturated at approximately 0.11 nm/cycle at pulse times of 3 seconds or longer. This result indicates that Y(MeCp)₂(iPr-nPrAMD) is chemisorbed in a self-limiting manner. FIG. 1(b) shows the growth rate of the Y₂O₃ thin film as a function of the H₂O pulse time at 260° C. In this case, the Y(MeCp)₂(iPr-nPrAMD) pulse, precursor purge, and reactant purge pulses were fixed at 3 seconds, 20seconds, and 20 seconds, respectively. As shown in FIG. 1(b), the growth rate of the Y₂O₃ thin film became saturated at approximately 0.11 nm/cycle for H₂O pulse times of 2 seconds or longer, confirming that a 2-second H₂O pulse is sufficient to fully react with the chemisorbed Y(MeCp)₂(iPr-nPrAMD) precursor. Accordingly, the saturated growth rate of the Y₂O₃ thin film at 260° C. was confirmed to be approximately 0.11 nm/cycle.

Another important aspect of ALD is that film thickness can be digitally controlled by repeated ALD cycles. Accordingly, as shown in FIG. 1(c), the dependence of the Y₂O₃ film thickness on the number of repeated ALD cycles was investigated. As shown in FIG. 1(c), the thickness of Y₂O₃ increased linearly as the number of ALD cycles increased from 300 to 900. In addition, the extrapolated line indicates no growth delay, suggesting rapid nucleation of Y₂O₃ during ALD.

Next, as shown in FIG. 1(d), the effect of growth temperature on the growth rate and refractive index of the Y₂O₃ thin film was investigated. As the growth temperature increased from 150° C. to 290° C., the growth rate of Y₂O₃ remained nearly constant, and no CVD-type growth was observed, indicating a wide ALD temperature window for Y₂O₃. In addition, a refractive index of approximately 1.87, which is close to that of bulk Y₂O₃ (1.9), was obtained within the ALD temperature window. Since the refractive index of a film generally depends on film density, it was expected that similar film densities could be obtained in the temperature range from 150° C. to 290° C. It should also be noted that the self-decomposition temperature of the Y(MeCp)₂(iPr-nPrAMD) precursor may be higher than 290° C., although this could not be confirmed due to the temperature limitation of the ALD equipment used, suggesting a possibility of extending the upper limit of the ALD temperature window.

The microstructure of the Y₂O₃ thin films was investigated by XRD as a function of growth temperature. As shown in FIG. 2(a), XRD patterns were obtained from Y₂O₃ thin films having similar thicknesses of approximately 30 nm by adjusting the number of ALD cycles in consideration of the growth rate at each temperature. As shown in FIG. 2(a), all Y₂O₃ thin films exhibited typical cubic polycrystalline phases corresponding to Y₂O₃ (JCPDS 31-1105), including the (222), (400), (431), and (440) planes, regardless of growth temperature. These characteristic phases were observed even at a low growth temperature of 150° C., which is likely attributable to the formation of dense and pure Y₂O₃ films. However, as the growth temperature increased, the amount of the Y₂O₃ (222) plane became dominant due to higher thermal energy, which is consistent with previous reports.

Accordingly, the effect of growth temperature on film density was investigated through XRR analysis. Film density was extracted from the position of the critical angle in FIG. 2(b). The film densities of the Y₂O₃—150, Y₂O₃—180, Y₂O₃—220, Y₂O₃—260, and Y₂O₃—290 samples were 4.88 g/cm³, 4.95 g/cm³, 5.0 g/cm³, 4.94 g/cm³, and 4.98 g/cm³, respectively. Regardless of growth temperature, all Y₂O₃ thin films exhibited film densities close to that of bulk Y₂O₃ (5.03 g/cm³), which supports the observation of well-crystallized phases even at 150° C. in the XRD results. Similarly, this explains the similar refractive index values (˜1.87) obtained within the ALD temperature window.

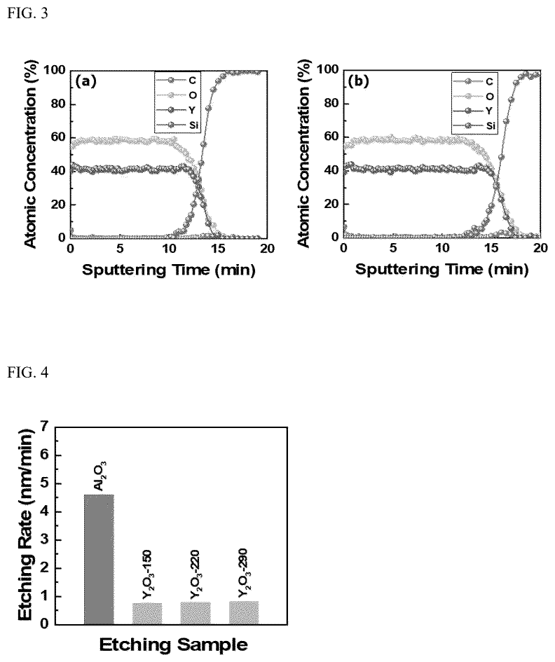

Further, AES depth profile studies were conducted to investigate the effect of growth temperature on the composition and impurities of the Y₂O₃ thin films. For this purpose, ALD-Y₂O₃ thin films grown at 150° C. and 290° C. were selected. As shown in FIGS. 3(a) and 3(b), stoichiometric Y₂O₃ thin films were successfully formed by ALD. In addition, carbon impurities were below the detection limit of AES, indicating that ligands of the Y(MeCp)₂(iPr-nPrAMD) precursor were completely removed through an optimized ALD process even at a low temperature of 150° C. Accordingly, the ALD-Y₂O₃ thin films exhibited high purity and high density and showed properties similar to bulk Y₂O₃, thereby confirming that they are promising films for various applications including protective coatings against CF₄-based plasma.

Plasma etching rates of ALD-Y₂O₃ thin films prepared at growth temperatures in the range of 150° C. to 290° C. were investigated using RIE at a plasma power of 400 W and a pressure of 50 mTorr, using a mixed gas of Ar (50 sccm), CF₄ (45 sccm), and O₂ (5 sccm). Among the etching gases used, Ar induces only physical etching due to its chemical stability. CF₄ is known to contribute to both chemical and physical etching, and O₂ is used to convert carbon generated by decomposition of CF₄ into CO₂ gas, thereby removing carbon from the film or silicon.

For the plasma etching process, Y₂O₃ thin films having a thickness of approximately 30 nm were used. In addition, for comparison, Al₂O₃ thin films having a thickness of approximately 110 nm were prepared by ALD at the same temperature of 150° C., and their etching behavior was compared with that of the ALD-Y₂O₃ thin films. After performing the RIE process for 15 minutes, plasma etching rates were calculated based on differences in film thickness.

As shown in FIG. 4, the Y₂O₃ thin film prepared at 150° C. exhibited a low plasma etching rate of 0.77 nm/min, whereas the Al₂O₃ thin film prepared at the same temperature exhibited a very high plasma etching rate of 4.6 nm/min, which is approximately six times higher than that of the Y₂O₃ thin film.

The difference in plasma etching rates between the two materials indicates that the Y₂O₃ thin film exhibits greater resistance to Ar/CF₄/O₂ plasma than the Al₂O₃ thin film. It is also noteworthy that the growth temperature had little effect on the dry etching behavior of the Y₂O₃ thin film under the gas conditions used. This is attributable to the high purity and high density of the ALD-Y₂O₃ thin film formed using the Y(MeCp)₂(iPr-nPrAMD) precursor and H₂O. These results can be explained by fluorination-based plasma chemical etching reactions of the Y₂O₃ and Al₂O₃ thin films, as follows:

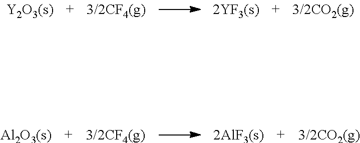

According to the above fluorination reaction scheme, Y₂O₃ and Al₂O₃ thin films are generally fluorinated at their surfaces to form YF₃ and AlF₃ surface layers, while CO₂ generated during the reaction is removed by a vacuum system. During this process, the YF₃ and AlF₃ surface layers are spontaneously formed due to negative values of standard formation enthalpy and standard Gibbs free energy.

Accordingly, when Y₂O₃ and Al₂O₃ thin films are exposed to Ar/CF₄/O₂ plasma, similar YF₃ and AlF₃ surface layers may be formed on the respective thin films. Formation of the YF₃ surface layer can reduce the erosion rate of the Y₂O₃ thin film due to its high boiling point of 2230° C., and formation of the AlF₃ surface layer may similarly reduce the erosion rate of the Al₂O₃ thin film. However, the lower boiling point of AlF₃ (1291° C.) indicates that AlF₃ is more susceptible to evaporation than YF₃.

Moreover, the physical etching rate of AlF₃ is significantly faster than that of YF₃, while it has been reported that the physical etching rates of Y₂O₃ and Al₂O₃ themselves are nearly similar. Therefore, the difference in plasma etching rates between Y₂O₃ and Al₂O₃ can be explained by continuous surface fluorination reactions and the corresponding physical etching rates of the formed fluoride layers.

As a result, Y₂O₃ undergoes less plasma erosion than Al₂O₃, suggesting that ALD-Y₂O₃ formed using the Y(MeCp)₂(iPr-nPrAMD) precursor and H₂O is a more promising protective coating than ALD-Al₂O₃.

### 4. Conclusion

The ALD-Y₂O₃ process using the Y(MeCp)₂(iPr-nPrAMD) precursor and H₂O as a reactant exhibited a wide ALD temperature window from 150° C. to 290° C., while showing a consistent growth rate and refractive index. In addition, the ALD-Y₂O₃ thin films exhibited a typical cubic polycrystalline phase regardless of growth temperature due to their high purity and high density, which are similar to those of bulk Y₂O₃.

Plasma etching rates of the ALD-Y₂O₃ thin films grown at various temperatures were investigated by reactive ion etching (RIE) at a plasma power of 400 W using an Ar/CF₄/O₂ mixed gas. For comparison, plasma etching rates of ALD-Al₂O₃ thin films were also investigated. When a growth temperature of 150° C. was applied to both ALD-Al₂O₃ and Y₂O₃ thin films, the ALD-Y₂O₃ thin film exhibited a significantly lower plasma etching rate than the ALD-Al₂O₃ thin film.

The difference in plasma etching rates between Y₂O₃ and Al₂O₃ was explained in detail based on continuous surface fluorination reactions and physical etching rates. It was also observed that the effect of growth temperature on the dry etching behavior of the Y₂O₃ thin films was minimal. Based on these results, ALD-Y₂O₃ formed using the Y(MeCp)₂(iPr-nPrAMD) precursor and H₂O can be considered a promising protective coating for semiconductor components and is suggested to be superior to ALD-Al₂O₃ in this respect.

The ALD-Y₂O₃ thin film formed using the Y(MeCp)₂(iPr-nPrAMD) precursor and H₂O according to the present invention may be applied as a protective coating to various semiconductor manufacturing components exposed to plasma during semiconductor manufacturing processes, including plasma showerheads, bellows, various piping materials, back pressure device components, laser heads, various fixtures, etching masks, wafer holders, and inner walls of chambers.

Unless otherwise defined, all technical and scientific terms used herein have the same meanings as commonly understood by one of ordinary skill in the art to which the present invention belongs. In addition, terms defined in generally used dictionaries are not to be interpreted ideally or excessively unless explicitly defined otherwise. Throughout the specification, when any portion is described as “including” a component, this does not exclude other components unless explicitly stated otherwise, and other components may be further included. In addition, singular forms may include plural forms depending on the context.

The scope of the present invention is not limited to the embodiments described above but is defined by the claims, and it is obvious that various modifications and variations may be made by those skilled in the art within the scope of the claims.

What is claimed is:

1. A method for manufacturing a Y₂O₃ thin film, comprising the steps of:
using Bis(methylcyclopentadienyl)(N′-isopropyl-N-n-propylacetamidinate)Yttrium (Y(MeCp)2(iPr-nPrAMD)) as a precursor,
employing atomic layer deposition (ALD), and
using one or more reactants selected from the group consisting of H₂O, O₃, O₂, and H₂O₂.

2. The method of claim 1, wherein one ALD cycle includes injecting Y(MeCp)₂(iPr-nPrAMD) with an inert gas at 30-100 sccm for a predetermined time t₁, purging with an inert gas at 30-100 sccm for time t₂, injecting an H₂O reactant at 30-100 sccm for time t₃, and again purging with an inert gas at 30-100 sccm for time t₄.

3. The method of claim 1, wherein a thin film growth temperature is controlled in a range from 150 °C to 350 °C.

4. The method of claim 2, wherein t₁ is 3 seconds or less.

5. The method of claim 2, wherein t₂ and t₄ are 18 to 22 seconds, and t₃ is 2 to 22 seconds.

6. The method of claim 4, wherein Y(MeCp)₂(iPr-nPrAMD) is chemisorbed in a self-limiting manner, such that a thickness of the formed Y₂O₃ thin film is linearly increased according to an increase in the number of ALD cycles.

7. A method for forming a protective coating material for a semiconductor manufacturing component, characterized in that a Y₂O₃ thin film is formed as a protective coating against fluorinated plasma chemical etching on a semiconductor manufacturing component by the method for manufacturing a Y₂O₃ thin film according to claim 1.

8. A semiconductor manufacturing component, characterized by including a Y₂O₃ protective coating material having resistance to fluorinated plasma chemical etching, formed by the method for forming a protective coating material for a semiconductor manufacturing component according to claim 7.
